(19) United States
(12) Patent Application Publication
(10) Pub. No.: US 2013/0032877 A1
(43) Pub. Date: Feb. 7, 2013

(54) N-CHANNEL TRANSISTOR COMPRISING A HIGH-K METAL GATE ELECTRODE STRUCTURE AND A REDUCED SERIES RESISTANCE BY EPITAXIALLY FORMED SEMICONDUCTOR MATERIAL IN THE DRAIN AND SOURCE AREAS

(71) Applicants: Ina OSTERMAY, Berlin (DE); Ralf ILLGEN, Dresden (DE); Stefan FLACHOWSKY, Dresden (DE)

(72) Inventors: Ina OSTERMAY, Berlin (DE); Ralf ILLGEN, Dresden (DE); Stefan FLACHOWSKY, Dresden (DE)

(73) Assignee: GLOBALFOUNDRIES Inc., Grand Cayman (KY)

(21) Appl. No.: 13/550,138

(22) Filed: Jul. 16, 2012

(30) Foreign Application Priority Data
Aug. 4, 2011 (DE) 10 2011 080 438.2

(51) Int. Cl. H01L 21/336; H01L 29/78

(52) U.S. Cl. 257/329; 438/268; 257/E21.41; 257/E29.262

(57) ABSTRACT

When forming sophisticated semiconductor devices including high-k metal gate electrode structures and N-channel transistors, superior performance may be achieved by incorporating epitaxially grown semiconductor materials, for instance a strain-inducing silicon/carbon alloy in combination with an N-doped silicon material, which may provide an acceptable sheet resistivity.

### BACKGROUND OF THE INVENTION

1. Field of the Invention

Generally, the present disclosure relates to the fabrication of highly sophisticated integrated circuits including at least N-channel transistors that comprise a high-k metal gate electrode structure, in combination with epitaxially grown materials, such as strain-inducing semiconductor alloys, formed in the drain and source areas.

2. Description of the Related Art

The fabrication of advanced integrated circuits, such as CPUs, storage devices, ASICs (application specific integrated circuits) and the like, requires a very large number of circuit elements to be formed on a given chip area according to a specified circuit layout, wherein field effect transistors represent one important type of circuit element that substantially determines performance of the integrated circuits. Currently, a plurality of process technologies are practiced, wherein, for many types of complex circuitry including field effect transistors, CMOS technology is one of the most promising approaches due to the superior characteristics in view of operating speed and/or power consumption and/or cost efficiency. During the fabrication of complex integrated circuits using CMOS technology, millions of transistors, i.e., N-channel transistors and P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a planar transistor architecture, the distance between the source and drain regions, which is also referred to as channel length.

Presently, most of the integrated circuits are formed on the basis of silicon due to its substantially unlimited availability, the well-understood characteristics of silicon and related materials and processes and the experience gathered during the past 50 years. Therefore, silicon will likely remain the material of choice for future circuit generations designed for mass products. One reason for the importance of silicon in fabricating semiconductor devices has been the superior characteristics of a silicon/silicon dioxide interface that allows reliable electrical insulation of different silicon regions from each other. The silicon/silicon dioxide interface is stable at high temperatures and, thus, allows performing subsequent high temperature processes as are required, for example, for anneal cycles to activate dopants and to cure crystal damage, without sacrificing the electrical characteristics of the interface.

For the reasons pointed out above, in field effect transistors, silicon dioxide has been preferably used as a base material for gate insulation layers that separate the gate electrode, frequently made of polysilicon, from the silicon channel region. In steadily improving device performance of field effect transistors, the length of the channel region has been continuously decreased to improve switching speed and drive current capability. Since the transistor performance is controlled by, among other things, the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be maintained. It turns out that decreasing the channel length for a planar transistor configuration requires an increased capacitive coupling in combination with sophisticated lateral and vertical dopant profiles in the drain and source regions to avoid the so-called short channel behavior during transistor operation. The short channel behavior may lead to an increased leakage current and to a pronounced dependence of the threshold voltage on the channel length. Aggressively scaled planar transistor devices with a relatively low supply voltage and thus reduced threshold voltage may suffer from an exponential increase of the leakage current due to the required enhanced capacitive coupling of the gate electrode to the channel region. That is, conventionally, the thickness of the silicon dioxide layer has been correspondingly reduced to provide the required capacitance between the gate electrode and the channel region. For example, a channel length of approximately 0.08 μm may require a gate dielectric made of silicon dioxide as thin as approximately 1.2 nm. The relatively high leakage current caused by the direct tunneling of charge carriers through an ultra-thin silicon dioxide gate insulation layer may, therefore, reach values for an oxide thickness in the range of 1-2 nm that may no longer be compatible with requirements for many types of circuits.

For this reason, new strategies have been developed in overcoming the limitations imposed by high leakage currents of extremely thin silicon oxide-based gate insulation layers. One very promising approach is the replacement of the conventional dielectric materials, at least partially, by dielectric materials having a dielectric constant that is significantly greater than the dielectric constant of silicon dioxide-based materials. For example, dielectric materials with a dielectric constant of 10.0 and significantly higher, also referred to as high-k dielectric materials, may be used, for instance in the form of hafnium oxide, zirconium oxide and the like. In addition to providing a high-k dielectric material in the gate insulation layers, also appropriate metal-containing materials may have to be incorporated since the required work function values for P-channel transistors and N-channel transistors may not be obtained on the basis of standard polysilicon gate materials in combination with the high-k dielectric material. To this end, appropriate metal-containing materials may be provided so as to cover the sensitive high-k dielectric materials and act as a source for incorporating an appropriate metal species, such as lanthanum, aluminum and the like, in order to appropriately adjust the work function for N-channel transistors and P-channel transistors, respectively. Furthermore, due to the presence of a metal-containing conductive material, the generation of a depletion zone, as may typically occur in polysilicon-based electrode materials, may be substantially avoided.

The process of fabricating a sophisticated gate electrode structure on the basis of a high-k dielectric material may require a moderately complex process sequence in order to adjust an appropriate work function for the transistors of different conductivity type and due to the fact that high-k dielectric materials may typically be very sensitive when exposed to certain process conditions, such as high temperatures in the presence of oxygen and the like.

In addition to providing sophisticated gate electrode structures, transistor performance may also be significantly enhanced by using a strain component in the channel region of at least one type of transistor, such as in P-channel transistors. It is well known that providing a compressive strain component along the current flow direction in a silicon channel region having a standard crystalline configuration may result in superior mobility of holes in the channel region, thereby also improving the drive current capability of the P-channel transistor. For this reason, a plurality of strain-inducing mechanisms have been developed, wherein one promising approach may be based on a strain-inducing semiconductor alloy, which is embedded into the active region of P-channel transistors after patterning the gate electrode structure. To this end, cavities may be formed in the active region laterally adjacent to the gate electrode structure and the cavities are subsequently refilled with a strain-inducing semiconductor alloy, such as a silicon/germanium material, which is grown in a strained state that in turn induces a desired compressive strain component in the channel region. The strain-inducing silicon/germanium material may be deposited on the basis of selective epitaxial growth techniques, in which process parameters are adjusted such that significant material deposition is restricted to crystalline silicon areas, while any material deposition on dielectric surface areas is suppressed. In order to avoid undue material growth on the gate electrode structures, the polysilicon material has to be reliably confined, at least during the selective epitaxial growth process. For this purpose, the gate electrode structures are typically provided with a dielectric cap material, such as a silicon nitride material, and a silicon nitride spacer layer is typically provided so as to cover the N-channel transistors, while the silicon nitride spacer layer is patterned into sidewall spacer elements at the gate electrode structure of the P-channel transistor, wherein, in the same etch sequence, also the corresponding cavities are formed in the active region of the P-channel transistor.

Moreover, upon further reducing the overall transistor dimensions, any performance-enhancing mechanisms, such as the strain-inducing semiconductor alloy provided in the P-channel transistors, may have an increased effect on the overall transistor performance. Therefore, the strain-inducing efficiency in the P-channel transistor is typically increased, for instance, by increasing the germanium concentration, reducing the lateral offset of the strain-inducing silicon/germanium material from the channel region and the like. In order to introduce similar performance-enhancing mechanisms for N-channel transistors, it has been proposed to incorporate a silicon/carbon material into the drain and source areas of N-channel transistors, which thus induces a desired tensile strain in the channel region. To this end, a carbon concentration of up to 2 atomic percent or more may be incorporated into the drain and source areas, thereby achieving a desired high tensile strain. In this manner, the electron mobility may be significantly increased, while, however, due to the presence of the carbon in the silicon base material, the series resistance of the semiconductor material is significantly increased. As a consequence, the advantages achieved by incorporating the carbon material for increasing the electron mobility may be compensated for or even overcompensated by the increase of the resistance in the active region so that, in total, transistor performance may not increase or may even drop. Since the finally achieved performance of complex transistors, such as N-channel transistors, depends on a plurality of factors, such as the strain conditions in the channel region, which in turn depend on the lateral offset of the strain-inducing material from the channel region, the basic electronic characteristics of the semiconductor material in the drain and source areas, the sheet resistivity of any metal silicide regions formed in the drain and source regions, the dopant concentration of drain and source extension regions and the like, a plurality of process strategies in the context of providing sophisticated high-k metal gate electrode structures have been proposed, wherein, however, performance improvement of N-channel transistors is less than expected.

In view of the situation described above, the present disclosure relates to semiconductor devices and manufacturing techniques in which N-channel transistors may be provided with superior performance on the basis of epitaxially grown semiconductor materials, while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques and semiconductor devices in which N-channel transistors may be formed on the basis of a strain-inducing semiconductor alloy or an N-doped semiconductor material formed by epitaxial growth techniques in order to generally increase performance of the transistor. In some illustrative embodiments, a strain-inducing carbon-containing semiconductor alloy is formed by epitaxial growth, wherein the advantageous effect of the increased electron mobility is obtained, however, without unduly contributing to an increased overall series resistance of the N-channel transistor. To this end, a semiconductor material is formed on the carbon-containing semiconductor alloy, preferably with a high dopant concentration, thereby reducing the sheet resistivity of a silicide material to be formed in the drain and source areas. Furthermore, in combination with drain and source extension regions provided in an early manufacturing stage, generally superior transistor performance may be achieved.

One illustrative method disclosed herein comprises forming a liner material on an active region and a gate electrode structure of an N-channel transistor, wherein the gate electrode structure is formed on the active region. The method further comprises forming drain and source extension regions in the active region. Additionally, the method comprises forming an N-doped semiconductor material by epitaxial growth so as to connect to the drain and source extension regions.

A further illustrative method disclosed herein relates to forming a semiconductor device. The method comprises forming a gate electrode structure above an active region and forming drain and source extension regions in the active region. Moreover, the method comprises forming a carbon-containing semiconductor alloy in the active region so as to connect to the drain and source extension regions. The method further comprises forming a semiconductor material selectively on the carbon-containing semiconductor alloy, wherein the semiconductor material has a reduced carbon concentration compared to the carbon-containing semiconductor alloy. Additionally, the method comprises forming a metal silicide in the semiconductor material.

One illustrative semiconductor device disclosed herein comprises a gate electrode structure formed on an active region of an N-channel transistor, wherein the gate electrode structure comprises a high-k dielectric material, a metal-containing electrode metal and a semiconductor electrode material. The semiconductor device further comprises a tensile strain-inducing semiconductor alloy formed in the active region of the N-channel transistor, wherein the tensile strain-inducing semiconductor alloy has a first carbon concentration. Additionally, the semiconductor device comprises a metal silicide formed above the tensile strain-inducing semiconductor alloy and having a second carbon concentration that is less than the first carbon concentration.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1h schematically illustrate cross-sectional views of a semiconductor device during various manufacturing stages, when an N-channel transistor is formed on the basis of an epitaxially grown and doped semiconductor material, possibly in combination with a strain-inducing semiconductor alloy, according to illustrative embodiments; and

FIGS. 2-3 schematically illustrate measurement results of N-channel transistors formed on the basis of principles disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure provides manufacturing techniques and semiconductor devices in which N-channel transistors may be formed on the basis of epitaxially grown semiconductor materials, which, in some illustrative embodiments, include a moderately high concentration of an N-type dopant species. For example, due to providing a semiconductor material by using epitaxial growth techniques, appropriate N-type dopant species, such as phosphorous, arsenic and the like, may be directly built into the lattice structure of the semiconductor base material with a significantly higher concentration compared to implantation due to the non-equilibrium conditions during the epitaxial growth process. In some illustrative embodiments, additionally, a strain-inducing semiconductor alloy in the form of a silicon/carbon alloy may be incorporated into the active region, wherein the additional N-doped semiconductor material formed on the silicon/carbon alloy substantially compensates for the increased resistance of a silicon/carbon material so that generally the increased electron mobility obtained by the strain conditions in the channel region contributes to superior transistor performance. For example, the sheet resistivity at the contact areas of the drain and source regions may be significantly reduced compared to conventional devices having formed therein a silicon/carbon material by using the highly N-doped semiconductor material as a cap material and by restricting a metal silicide to this semiconductor material, which in turn appropriately connects to the strain-inducing silicon/carbon alloy and to drain and source extension regions, which may be formed in an early manufacturing stage, i.e., prior to incorporating the strain-inducing semiconductor alloy. Furthermore, formation of the drain and source extension regions and the subsequent strain-inducing semiconductor alloy is compatible with providing a high-k a metal gate electrode structure, any sensitive materials of which may be appropriately confined on the basis of a protective liner material and offset spacers that are also used for adjusting the lateral distance of the epitaxially grown semiconductor materials or alloys.

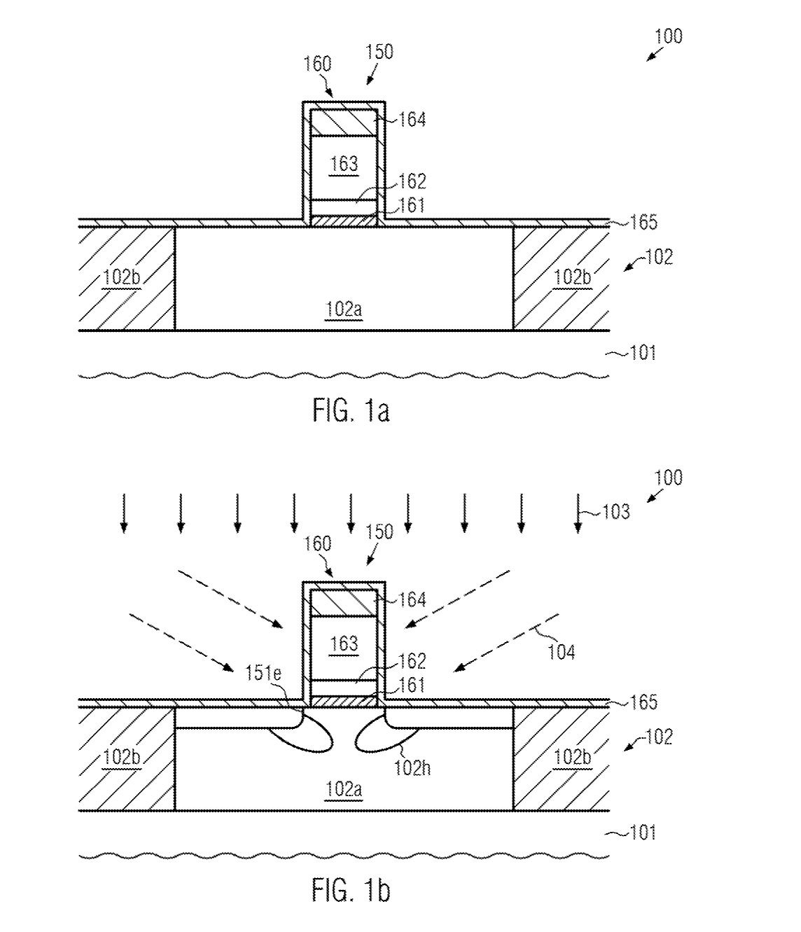

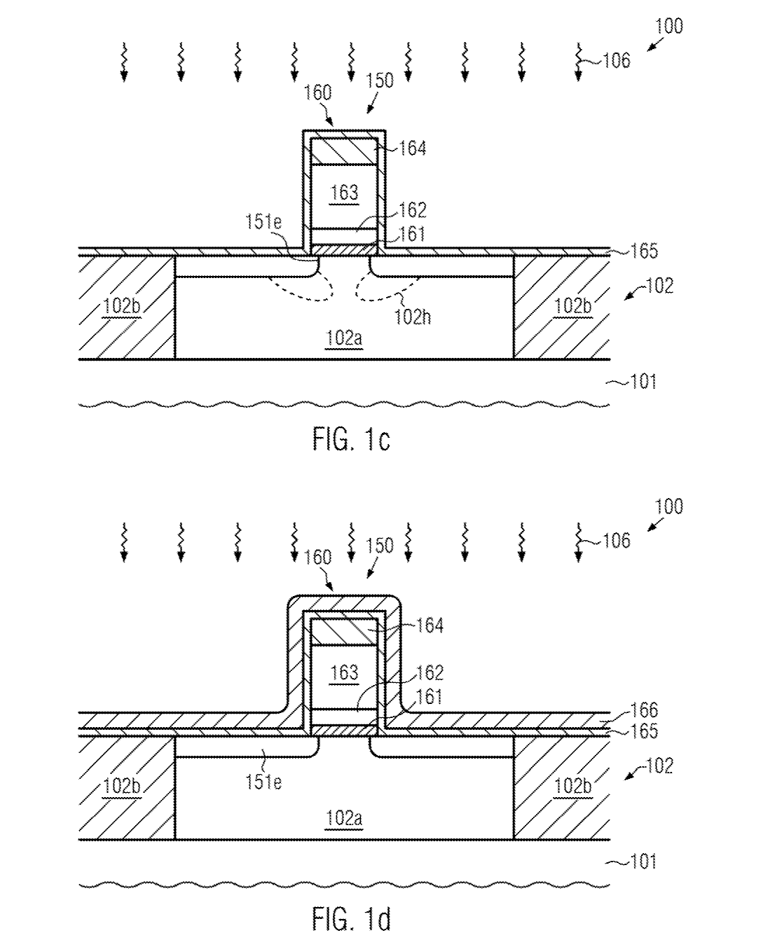

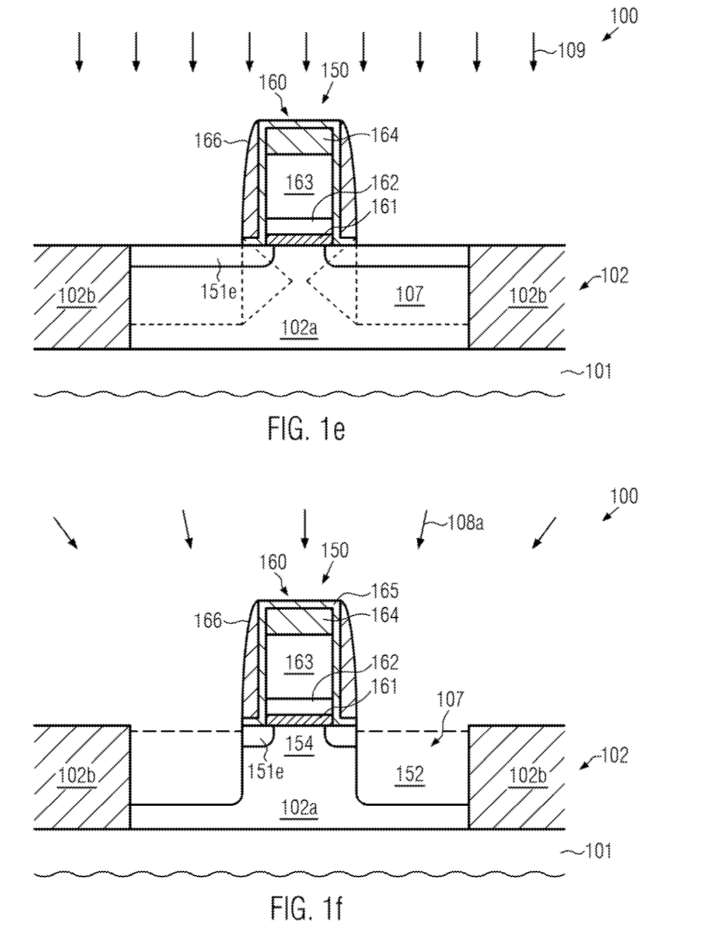

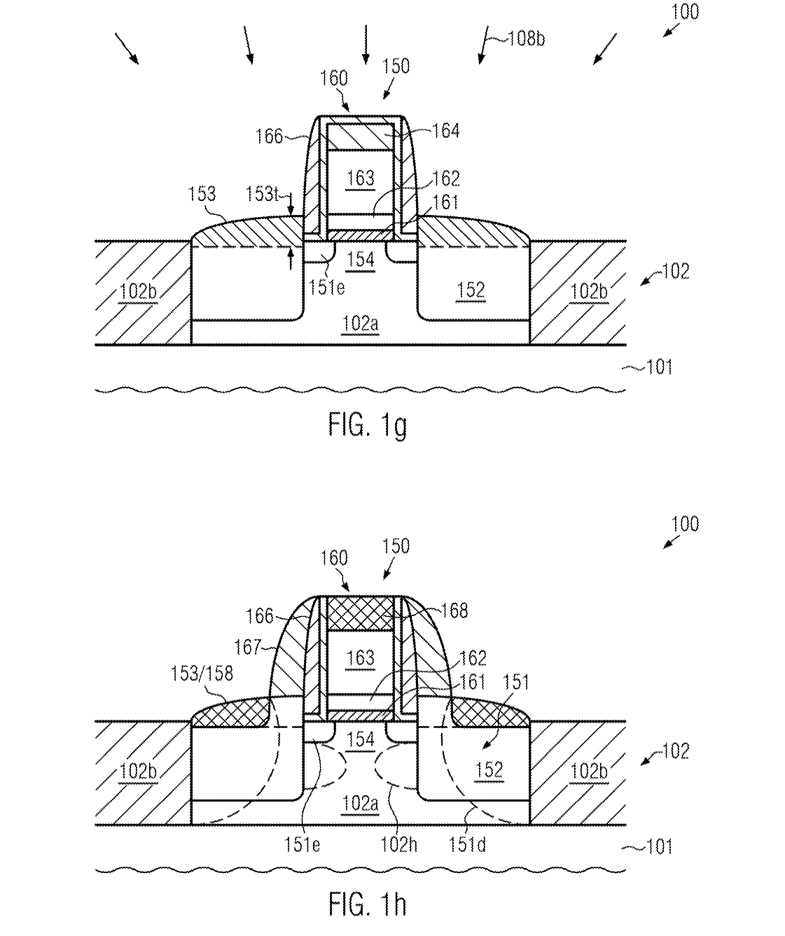

FIG. 1a schematically illustrates a cross-sectional view of a semiconductor device 100 comprising a substrate 101, above which is provided a semiconductor layer 102. The semiconductor layer 102 is typically divided into a plurality of semiconductor regions or active regions, which are to be understood as regions in and above which at least one transistor is to be formed. For convenience, a single active region 102a is illustrated in FIG. 1a and represents the active region of an N-channel transistor 150. The active region 102a is laterally delineated by an isolation region 102b, which may have any appropriate configuration and which may be provided, for instance, in the form of a shallow trench isolation. It should be appreciated that a buried insulating layer (not shown) may be positioned between the semiconductor layer 102 and the substrate 101 if a silicon-on-insulator (SOI) architecture is considered. In other cases, the silicon base material of the active region 102a is directly in connection with the crystalline material of the substrate 101, in which case a bulk configuration is provided.

In this manufacturing stage, the transistor 150 comprises a gate electrode structure 160, which in turn may comprise a gate dielectric layer 161 including a high-k dielectric material, possibly in combination with a conventional dielectric material, depending on the overall process and device requirements. For example, the gate dielectric layer 161 may comprise hafnium oxide, zirconium oxide and the like. Furthermore, a metal-containing electrode material 162, such as titanium nitride, tantalum nitride and the like, may be formed above the gate dielectric layer 161, followed by a semiconductor-based electrode material 163, such as amorphous and/or polycrystalline silicon and the like. Furthermore, a dielectric cap layer or layer system 164, such as a silicon nitride material, is typically formed on the electrode material 163. The gate electrode structure 160 may have any appropriate gate length, i.e., in FIG. 1a the horizontal extension of the material 162, for example, a gate length of 50 nm and less, such as 35 nm and less, may be implemented in sophisticated semiconductor devices. In this manufacturing stage, the gate electrode structure 160 and the active region 102a are covered by a protective liner or liner system 165, for instance comprised of silicon nitride, silicon dioxide and the like.

The semiconductor device 100 as shown in FIG. 1a may be formed on the basis of the following process strategy. The isolation region 102b may be formed on the basis of sophisticated lithography, etch, deposition, anneal and planarization techniques, thereby also defining the lateral size, position and shape of the active region 102a. Prior to or after forming the isolation region 102b, well dopant species may be incorporated into the active region 102a so as to adjust the basic electronic characteristics for an N-channel transistor to be formed in and above the active region 102a. Next, the process sequence is applied in which the sensitive materials 161 and 162 are formed, which may include appropriate deposition and patterning strategies in order to provide a high-k dielectric material in combination with a metal-containing electrode material, wherein, if required, additional anneal processes may be applied so as to incorporate a work function adjusting metal species, such as lanthanum, in the dielectric layer 161 and/or in the electrode layer 162. Thereafter, the semiconductor material 163 in combination with one or more cap materials, such as the layer 164, are deposited by applying any appropriate deposition technique, followed by a complex lithography and etch sequence in order to form the gate electrode structure 160 from the resulting layer stack. Consequently, on the basis of the above-described process sequence, the electronic characteristics of the high-k metal gate electrode structure 160 may be adjusted in an early manufacturing stage, which, however, requires a reliable confinement of the sensitive materials 161, 162. To this end, the liner 165 is provided, for instance in the form of a silicon dioxide material, a silicon nitride material or possibly a combination of these layers, which may be deposited by using well-established deposition techniques, such as multi-layer deposition processes and the like.

FIG. 1b schematically illustrates the semiconductor device 100 in a further advanced manufacturing stage. As shown, an implantation sequence may be applied in order to introduce dopant species into the active region 102a. To this end, an implantation process 103 may be performed so as to incorporate drain and source dopant species, thereby preliminarily forming drain and source extension regions 151e having a desired dopant concentration and depth. The implantation process 103 may be performed on the basis of appropriate process parameters so as to incorporate the dopant species through the layer 165. Moreover, a tilted implantation process sequence 104 may be applied so as to incorporate a counter-doping species with respect to the dopant species of the drain and source extension regions 151e, thereby forming counter-doped regions or halo regions 102h. It should be appreciated that other device areas may be reliably covered by appropriate implantation masks in accordance with well-established masking regimes. Hence, during the implantation processes 103, 104 and associated resist removal processes, the sensitive materials of the gate electrode structure 160 may be reliably covered by the liner 165.

FIG. 1c schematically illustrates the semiconductor device 100 during an anneal process 106, in which appropriate temperatures are applied to the device 100 so as to re-crystallize implantation-induced damage in the active region 102a. Moreover, appropriate activation of the dopant species may be accomplished during the process 106. For this purpose, any well-established techniques, such as laser-based anneal processes, rapid thermal anneal techniques, flashlight-based anneal processes and the like, may be applied. Moreover, if required, a certain degree of diffusion of the dopant species may be initiated during the process 106, thereby defining the desired lateral overlap of the extension regions 151e with the gate electrode structure 160. Consequently, after any anneal process 106, the extension regions 151e and the halo regions 102h have appropriate configurations, while also a desired high crystal quality has been reestablished prior to incorporating a semiconductor material or a semiconductor alloy on the basis of a selective epitaxial growth process.

FIG. 1d schematically illustrates the semiconductor device 100 in a further advanced manufacturing stage. As shown, a spacer layer 166 may be formed above the active region 102a and the gate electrode structure 160, for instance comprised of silicon nitride and the like. The spacer layer 166 may be deposited by using any well-established deposition recipe so as to provide an initial layer thickness and the material composition, which may ensure obtaining appropriately dimensioned spacer elements after patterning the spacer layer 166.

FIG. 1e schematically illustrates the semiconductor device 100 when exposed to a reactive process atmosphere in order to perform an etch sequence 109. During the process sequence 109, the previously provided spacer layer 166 may be patterned into spacer elements, which are also indicated by reference number 166, which then determine or at least significantly influence the size and shape and, thus, the lateral offset of cavities 107 to be formed in the active region 102a when continuing the etch sequence 109. Consequently, the spacer elements 166 preserve a certain portion of the drain and source extension regions 151e during the subsequent process phase of the sequence 109, in which material of the active region 102a is removed. Typically, the spacer elements 166 are patterned on the basis of a plasma assisted etch process, which in some cases may be continued on the basis of an appropriate etch chemistry so as to etch into the active region 102a. In other cases, the sequence 109 may comprise a wet chemical etch process, for instance using chemicals like TMAH (tetramethyl ammonium hydroxide), potassium hydroxide (KOH) and the like, which exhibits a crystallographically anisotropic etch behavior. In this case, the cavities 107 may have a well-defined lateral configuration, since certain crystal planes, such as (111) planes, may act as etch stop layers. The wet chemical etch step may be preceded by a plasma assisted etch process in some illustrative embodiments, wherein, however, irrespective of the process sequence applied, nevertheless at least a portion of the drain and source extension regions 151e is preserved below the spacer elements 166.

FIG. 1f schematically illustrates the semiconductor device 100 in a further advanced manufacturing stage. As illustrated, a first selective epitaxial growth process 108a may be applied in some illustrative embodiments in order to form an appropriate semiconductor material within the cavities 107 or at least within a portion of these cavities. The actual deposition of a semiconductor material may be preceded by any appropriate cleaning processes in order to prepare exposed semiconductor surface areas for the subsequent selective deposition of a semiconductor material. During this phase and during the subsequent deposition of material, sensitive parts of the gate electrode structure 160 are reliably protected by the spacer elements 166, the liner 165 and the cap layer 164. In one illustrative embodiment, the deposition process 108a may be performed so as to incorporate a strain-inducing carbon-containing semiconductor material 152, which may also be referred to as a semiconductor alloy. As is well known, silicon/carbon material, when grown in a crystalline state, may have a reduced lattice constant compared to silicon material. Consequently, since the remaining material of the active region 102a acts as a template material during the deposition 108a, the material 152 is grown in a strained state, which in turn results in a tensile strain in a channel region 154. For example, the carbon-containing semiconductor alloy 152 may be provided with a carbon content of approximately 1 atomic percent and higher, such as 2 atomic percent and higher, in order to provide highly efficient strain conditions in the channel region 154. On the other hand, as discussed above, the increased carbon content in the material 152 may increase the resistance of the material compared to a doped silicon material, which, however, may be efficiently compensated for by providing a further epitaxially grown semiconductor material and by providing the extension regions 151e having a desired depth and dopant concentration as determined by the previously applied process sequence. Moreover, in some illustrative embodiments, the material 152, when provided as a silicon/carbon alloy, may also be doped in situ by supplying an appropriate precursor gas during the deposition 108a in order to obtain a high dopant concentration in the material 152. To this end, any appropriate N-type dopant species, such as phosphorous, arsenic and the like, may be incorporated during the deposition. It should be appreciated that, due to the non-equilibrium conditions of the selective growth process, a significantly higher dopant concentration may be implemented in the material 152 compared to conventional processes and devices, in which the drain and source dopant species are incorporated by ion implantation. Furthermore, the dopant atoms are positioned at lattice sites without creating undue stacking faults, which may typically be encountered after implantation and a subsequent anneal process. Consequently, in these embodiments, the semiconductor material 152 may be provided as a strain-inducing carbon-containing alloy having a high dopant concentration, thereby efficiently compensating, at least to a certain degree, that generally increased resistance of a silicon/carbon material. On the other hand, superior electron mobility is accomplished in the channel region 154.

It should be appreciated that the material 152 may be formed in the cavities 107 up to a height level so as to connect to the drain and source extension regions 151e, wherein, however, a further semiconductor material to be formed on the material 152 may also efficiently connect to the drain and source extension regions 151e.

In further illustrative embodiments, the semiconductor material 152 may be provided as a highly doped silicon material, such as a phosphorous doped silicon material, wherein the moderately high phosphorous concentration may result in a certain strain-inducing effect while at the same time ensuring high conductivity and superior crystalline quality of the material 152.

FIG. 1g schematically illustrates the semiconductor device 100 during a further epitaxial growth process 108b, in which a semiconductor material 153 may be formed on the previously deposited material 152. To this end, the deposition atmosphere of the process 108b may be established on the basis of appropriate precursor gasses, for instance in the same process reactor that has been used for the deposition process 108a of FIG. 1f, without exposing the device to ambient atmosphere in order to obtain the material 153 with required characteristics. In one illustrative embodiment, the material 153 is provided as a semiconductor material having reduced carbon content with respect to the material 152 in order to avoid undue reduction of the overall conductivity caused by the presence of the carbon species in a silicon material. In some illustrative embodiments, the material 153 may be provided as a substantially carbon-free material, which is to be understood as a semiconductor material having a maximum carbon concentration of 0.1 atomic percent and less. Preferably, the carbon concentration is less than 0.01 atomic percent. For example, a substantially intrinsic silicon material may be provided during the process 108b, while in other cases a desired high dopant concentration may be incorporated into the material 153, which may be accomplished by adding an N-type dopant species, such as phosphorous, to the deposition atmosphere of the process 108b. In this case, the material 153 may be referred to as a “carbon free” material, even if minute amounts of carbon may be incorporated to any imperfections of the process tools and material sources used. In some illustrative embodiments, as shown in FIG. 1g, the semiconductor material 153 may thus connect to the material 152 and also to the drain and source extension regions 151e. Hence, a low resistance path may be established from the material 153 to the drain and source extension regions 151e and thus to the channel region 154 due to a high dopant concentration, if provided, and/or due to the incorporation of a metal silicide in a further advanced manufacturing stage.

The semiconductor material 153 may be advantageously formed with a thickness 153t that is appropriately selected so as to generally provide superior sheet resistivity, irrespective of the presence of carbon species in the material 152. To this end, it has been recognized that a thickness of 25-35 nm may result in an appropriate overall sheet resistivity of the drain and source areas. It is to be noted that the thickness 153t refers to a thickness of the material 153 in close proximity to the gate electrode structure 160, i.e. at or in close proximity to the spacer structure 166, while the thickness of the material 153 at the periphery of the active region 102a may be reduced due to any edge effects during the epitaxial growth process. In some illustrative embodiments, the thickness 153t is selected such that a metal silicide may be formed within the material 153 without consuming a portion of the material 152, which, in some cases, may have incorporated therein a desired high carbon concentration. Consequently, in this case, the metal silicide is restricted to a material portion in which substantially no carbon or at least a significantly reduced carbon concentration is present compared to the material 152, if this material is provided as a strain-inducing silicon/carbon alloy.

Consequently, the semiconductor material 153 may be provided with an appropriate thickness that enables an efficient connection to the drain and source extension regions 151e and that ensures superior sheet resistivity, for instance due to a very high dopant concentration, for instance by using phosphorous, and/or due to the fact that a metal silicide may be formed highly efficiently within the material 153, thereby contributing to increased current flow into the extension regions 151e and into the channel 154 without requiring extensive current flow through the material 152, which may have incorporated a high carbon concentration so as to induce a desired high tensile strain in the channel region 154.

FIG. 1h schematically illustrates a cross-sectional view of the semiconductor device 100 in a further advanced manufacturing stage. As shown, the transistor 150 may comprise drain and source regions 151, which in turn may include the drain and source extension regions 151e and the semiconductor alloy 152, if provided as a doped semiconductor material. That is, as discussed above, in some illustrative embodiments, the semiconductor alloy or generally the semiconductor material 152 may be provided as a highly N-doped semiconductor material with a high degree of dopant activation and a superior crystalline structure. In this case, an additional implantation process may be avoided, thereby preserving the superior crystal quality. In other cases, the drain and source regions 151 may be formed on the basis of an additional implantation process in order to incorporate drain and source dopant species, thereby forming deep drain and source regions 151d. In other cases, additional dopant species may be incorporated by ion implantation, while also a desired high dopant concentration may have been incorporated on the basis of the semiconductor material 152 and possibly on the basis of the semiconductor material 153.

Hence, in the active region 102a, a desired dopant profile is established on the basis of the drain and source extension regions 151e formed in an early manufacturing stage, as discussed above, the halo regions 102h and on the basis of the optional deep drain and source regions 151d and/or the material 152. Moreover, in embodiments in which the semiconductor material 152 is provided as a strain-inducing alloy, a desired high tensile strain component is induced in the channel region 154, as discussed above. Furthermore, a metal silicide 158 may be formed in the drain and source regions 151, thereby providing appropriate contact areas of the transistor 150. In some illustrative embodiments, as explained before, the metal silicide 158 may be formed so as to be restricted to the semiconductor material 153 having a desired reduced carbon concentration, thereby forming a low resistance path to the channel region 154. Hence, the metal silicide 158 and the remaining material 153 may have a significantly lesser carbon concentration compared to the material 152, if provided as a silicon/carbon alloy.

Similarly, the gate electrode structure 160, which may comprise an additional spacer structure 167, may have incorporated in the semiconductor electrode material 163 a metal silicide 168, thereby also imparting superior conductivity to the gate electrode structure 160.

The semiconductor device 100 as shown in FIG. 1h may be formed by any appropriate process strategies including the removal of the cap layer 164 (FIG. 1g), the deposition of appropriate spacer materials, such as silicon dioxide, silicon nitride and the like, and the patterning of the layer into the spacer structure 167 using well-established etch strategies. Thereafter, if required, additional drain and source dopant species may be incorporated, for instance for forming the deep drain and source regions 151d, followed by any further process so as to activate dopant and re-crystallize implantation-induced damage. In other cases, a further incorporation of N-type dopant species into the active region 102a may not be required due to the moderately high dopant concentration in the materials 152 and 153, wherein, if required, an additional anneal process may be applied so as to initiate a further dopant diffusion, so as to adjust the final lateral and vertical profile of the drain and source regions 151. Next, a silicidation process may be applied by using the spacer structure 167 as a mask, thereby also defining the lateral offset of the metal silicide 158 from the extension regions 151e. As discussed above, in some illustrative embodiments, the silicidation process is adjusted such that the silicide 158 is formed entirely within the material 153 so as to not unduly consume strain-inducing material and to avoid undue current flow through the material 152, if comprising a significant amount of carbon.

Consequently, the transistor 150 may generally exhibit superior performance due to the superior strain conditions, if the material 152 is provided as a tensile strain-inducing semiconductor alloy, and due to the increased dopant concentration, which may be incorporated into the material 152 upon the selective epitaxial growth process. Furthermore, the additional semiconductor material 153 may also provide superior sheet resistivity, even if a desired high carbon concentration is incorporated in the material 152, so as to obtain a low resistance current path from the metal silicide 158 into the extension regions 151e and finally to the channel region 154.

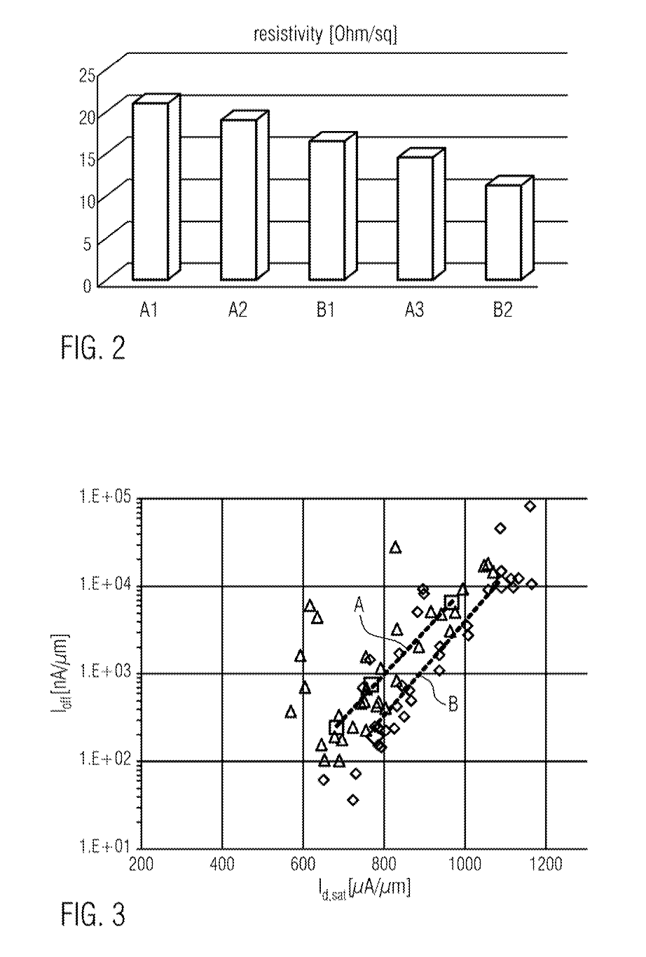

FIG. 2 schematically illustrates measurement results of sheet resistivities between metal silicide and the active silicon region, for instance the metal silicide 158 and the channel region 154 of the transistor 150 of FIG. 1h, wherein various samples have been prepared on the basis of the same design parameters except for the semiconductor material 153. The vertical axis in FIG. 2 represents the sheet resistivity, while the horizontal axis represents the various samples. For example, sample A3 corresponds to a conventional configuration in which a metal silicide is formed in a phosphorus implanted silicon base material without a silicon/carbon alloy. Sample A1 represents the situation in which no phosphorus doped silicon material is provided above a silicon/carbon alloy, while sample A2 represents an example in which the phosphorus doped silicon material for forming therein a metal silicide and positioned above a silicon/carbon alloy has a thickness of 15 nm. On the other hand, samples B1 and B2 have been prepared according to the principles disclosed herein, i.e., a thickness of the material 153 (FIG. 1h) is in the range of 25-35 nm. It should be appreciated that samples A1, A2, B1, A3 have been prepared so as to include a strain-inducing silicon/carbon alloy, while sample B2 corresponds to a situation in which no strain-inducing semiconductor alloy is provided. That is, as discussed above, the semiconductor material 152 and the material 153 may be provided as highly phosphorus doped or generally N-doped semiconductor materials that have been epitaxially grown in order to provide superior overall conductivity of N-channel transistors. As is evident from FIG. 2, a thickness of 25 nm or more of the material 153 results in a sheet resistivity that is comparable to or less than the sheet resistivity of the “reference” sample A3 so that a negative influence of the carbon species on the sheet resistivity is substantially compensated for.

FIG. 3 schematically illustrates performance of conventional N-channel transistors indicated by curve A, while curve B represents transistors formed on the basis of the principles disclosed herein. In particular, the corresponding transistors have been prepared by incorporating a silicon/carbon alloy in order to induce a tensile strain in the channel regions, as discussed above, wherein the transistors representing curve A are provided without the material 153 (FIG. 1h), while the transistors represented by curve B have implemented therein the material 153 provided in the form of a phosphorus doped silicon material.

Curve A and B represent performance of the transistors in terms of the saturation current (horizontal axis) versus off-current (vertical axis). As is evident from FIG. 3, a significant shift may be achieved, thereby indicating increased saturation currents for the same off-current of transistors formed on the basis of the present disclosure.

As a result, the present disclosure provides manufacturing techniques and semiconductor devices in which N-channel transistors may be formed on the basis of epitaxially grown semiconductor materials, such as a strain-inducing silicon/carbon alloy, in combination with a further epitaxially grown semiconductor material as a cap layer that provides, in combination with a metal silicide, a lower sheet resistivity, even if a significant amount of carbon is incorporated in the drain and source areas. In this manner, the superior electron mobility obtained by the tensile strain conditions in the channel region is not unduly reduced by the generally increased resistance of a silicon/carbon alloy. Furthermore, superior connection to the drain and source extension regions may be accomplished by implementing these regions in an early manufacturing stage. Thus, sophisticated high-k metal gate electrode structures may be provided in an early manufacturing stage, wherein sensitive gate materials may be reliably confined without unduly affecting the incorporation of a strain-inducing mechanism on the basis of a silicon/carbon alloy.

It should further be appreciated that the above-described process strategy may be readily implemented into any manufacturing regime, in which also a strain-inducing mechanism is applied to P-channel transistors. For example, separate process sequences may be applied for individually incorporating a strain-inducing material into the active regions of P-channel transistors and N-channel transistors. Furthermore, in this case, also an appropriately doped silicon material may be provided as a cap material for the P-channel transistors in order to provide superior and similar conditions during the fabrication of a metal silicide in P-channel transistors and N-channel transistors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a liner material on an active region and a gate electrode structure of an N-channel transistor, said gate electrode structure being formed on said active region;
forming drain and source extension regions in said active region; and
forming an N-doped semiconductor material by epitaxial growth so as to connect to said drain and source extension regions.

2. The method of claim 1, further comprising forming a tensile strain-inducing semiconductor alloy in said active region after forming said drain and source extension regions.

3. The method of claim 2, wherein forming said tensile strain-inducing semiconductor alloy comprises forming a silicon/carbon alloy with a carbon concentration of 1 atomic percent or higher.

4. The method of claim 2, wherein forming said tensile strain-inducing semiconductor alloy comprises incorporating an N-type dopant species during epitaxial growth of said tensile strain-inducing semiconductor alloy.

5. The method of claim 3, wherein forming said N-doped semiconductor material comprises depositing a semiconductor material with a carbon concentration of 0.1 atomic percent or less.

6. The method of claim 1, further comprising forming a metal silicide in said epitaxially grown N-doped semiconductor material.

7. The method of claim 6, wherein formation of said metal silicide is restricted to said epitaxially grown N-doped semiconductor material.

8. The method of claim 1, wherein said N-doped semiconductor material is formed with a thickness of approximately 25-35 nm.

9. The method of claim 1, further comprising forming said gate electrode structure so as to comprise a high-k dielectric material prior to forming said liner material.

10. The method of claim 1, further comprising reducing lattice damage after forming said drain and source extension regions by performing an anneal process prior to forming said N-doped semiconductor material.

11. A method of forming a semiconductor device, the method comprising:
forming a gate electrode structure above an active region;
forming drain and source extension regions in said active region;
forming a carbon-containing semiconductor alloy in said active region so as to connect to said drain and source extension regions;
forming a semiconductor material selectively on said carbon-containing semiconductor alloy, said semiconductor material having a reduced carbon concentration compared to said carbon\-containing semiconductor alloy; and
forming a metal silicide in said semiconductor material.

12. The method of claim 11, wherein forming said carbon-containing semiconductor alloy comprises performing a selective epitaxial growth process and incorporating an N-type dopant species during said epitaxial growth process.

13. The method of claim 11, wherein forming said semiconductor material comprises performing an epitaxial growth process and incorporating an N-type dopant species during said epitaxial growth process.

14. The method of claim 13, wherein a dopant concentration of said N-type dopant species is adjusted to 0.1 atomic percent or higher.

15. The method of claim 11, further comprising forming a protective liner material on said gate electrode structure prior to forming said drain and source extension regions.

16. The method of claim 15, further comprising forming an offset spacer on said gate electrode structure after forming said drain and source regions and prior to forming said carbon-containing semiconductor alloy.

17. The method of claim 11, wherein formation of said metal silicide is restricted to said semiconductor material.

18. The method of claim 15, wherein forming said gate electrode structure comprises forming a high-k dielectric material and a metal-containing electrode material prior to forming said protective liner.

19. The method of claim 11, wherein said semiconductor material is formed with a thickness in the range of 25-35 nm.

20. A semiconductor device, comprising:
a gate electrode structure formed on an active region of an N-channel transistor, said gate electrode structure comprising a high-k dielectric material, a metal-containing electrode metal and a semiconductor electrode material;
a tensile strain-inducing semiconductor alloy formed in said active region of said N-channel transistor, said tensile strain-inducing semiconductor alloy having a first carbon concentration; and
a metal silicide formed above said tensile strain-inducing semiconductor alloy and having a second carbon concentration that is less than said first carbon concentration.
